(19) United States
(12) Patent Application Publication
(10) Pub. No.: US 2010/0133577 A1
(43) Pub. Date: Jun. 3, 2010

(54) Method for producing electronic component and electronic component

(76) Inventors: Werner Hoffmann, Kummersbruck (DE); Roland Höfer, Freudenberg (DE); Herbert Schwarzbauer, Munchen (DE); Karl Weidner, Munchen (DE)

Correspondence Address: STAAS & HALSEY LLP, SUITE 700, 1201 NEW YORK AVENUE, N.W., WASHINGTON, DC, 20005, US

(21) Appl. No.: 12/452,955

(22) PCT Filed: Jul. 17, 2008
(86) PCT No.: PCT/EP2008/059368

§ 371 Date: Jan. 29, 2010

(30) Foreign Application Priority Data
Jul. 31, 2007 (DE) 10 2007 035 902.2

(51) Int. Cl. H01L 23/522; H01L 21/56; H01L 33/00

(52) U.S. Cl. 257/99; 438/110; 257/773; 257/E21.502; 257/E23.142; 257/E33.066

(57) ABSTRACT

A plurality of chips disposed in a wafer on a passivated main side, having at least one chip contact surface, is provided with an insulation layer. The insulation layer has openings in the area of the at least one chip contact surface of each chip. The chip contact surfaces of each chip are provided with a chip contact surface metallization of a prescribed thickness, and the chips disposed in the water are separated therefrom.

### CROSS REFERENCE TO RELATED APPLICATIONS

This application is the U.S. national stage of International Application No. PCT/EP2008/059368, filed Jul. 17, 2008 and claims the benefit thereof. The International Application claims the benefit of German Application No. 10 2007 035 902.2 filed on Jul. 31, 2007, both applications are incorporated by reference herein in their entirety.

### BACKGROUND

Described below are a method for producing an electronic component and an electronic component.

An electronic component usually includes a carrier or a substrate, to which a structured metal layer with metal or contact surfaces is applied. Applied to many of the contact surfaces are one or more respective components, e.g. a semiconductor chip or passive component. The component or components is or are connected to the respective contact surface by a connection, generally solder. Provided one of the components has a rear-side contact, i.e. a contact facing towards the carrier or the substrate, not only is a mechanical but also an electrical connection established through the solder to the respective contact surface. For electrical contacting at least some of the components each have a number of contact surfaces on their upper side facing away from the carrier. The electrical connection between the various contact surfaces and/or to one of the contact surfaces of the metal layer is usually implemented using bond wires.

As an alternative it is possible to establish electrical connections between the various contact surfaces and/or to a contact surface of the metal layer using a so-called planar connection technology, in which one surface of the semi-finished product is first covered by an insulation layer, e.g. a plastic tape made from an insulating material. Contact point openings are made in the insulation layer at the points where the contact surfaces are located in order to reveal the contact surfaces. Subsequently a thin metallic layer is applied by sputtering, by vapor deposition or by another method to create thin contact layers over the entire surface of the insulation layer and the openings made in it. A further light-sensitive tape (known as photo tape) generally formed of an insulating material is then applied to this thin metal layer. The photo tape is exposed and developed in a further operation according to the desired conducting structure. The non-exposed sections of the photo tape can be removed in a further operation, so that the thin metal layer lying beneath them, more precisely the copper surface, is revealed. By immersing the prepared semi-finished product in a bath of electrolyte, especially a bath of copper electrolyte, an appr. 20 μm to 200 μm thick copper layer is grown by galvanic reinforcement. In a subsequent operation, which is referred to as stripping the photo tape, the photo tape still present on the surface is removed in the areas at which no electrically-conducting structure is to be embodied. As a last operation a so-called differential etching is undertaken, in which the thin metal surface of titanium and copper is removed from the entire surface, so that only the desired conductive structure is left. The conductive structure, which is also referred to as the contact conductor track structure, is usually embodied from copper, with its layer thickness ranging from 20 μm to 500 μm.

Electronic modules that are produced in planar connection technology have the advantage that the height of a completed electronic module is significantly smaller compared to an electronic module with known bond wires.

However planar connection technology also has a series of disadvantages. The contact conductor track structure is often produced using a laser ablation process. This is very cost-intensive and causes the formation of laser residues which then makes an expensive cleaning process necessary. Fusion zones of different focal positions can form, delaminations on border surfaces have also been observed. Under some circumstances the laser ablation process results in the complete removal of any fillers and resin materials that might be involved in the insulation layer. From time to time damage to the chip contact surfaces of the components is also noticed.

### SUMMARY

It is thus an aspect to specify a method for producing an in particular planar electronic module which makes it possible to produce the module in a simpler and lower-cost manner while simultaneously increasing the yield. In addition an electronic module is to be specified which is able to be produced at low cost and exhibits a high reliability.

In a method for producing an, especially planar, electronic module a plurality of chips arranged on a wafer are provided with an insulation layer on a main side provided with at least one chip contact surface and passivated. The insulation layer is provided in the area of the at least one chip contact surface of respective chips with openings. The chip contact surfaces of the respective chips are provided with a chip contact surface metallization of a predetermined thickness. Finally the chips arranged in the wafer are diced from the latter.

By contrast with the production process of a planar electronic module described at the start, the method creates the chip contact surface metallizations (and, in an embodiment, only these) already at the wafer level. This procedure has the advantage that on the one hand the coating with the insulation layer in the planar state can be undertaken with simple and widely-used coating methods. Furthermore the application of the chip contact surface metallizations can be undertaken using galvanic methods with practically no limits being set in respect of the thickness of the chip contact surface metallizations.

The insulation layer which is applied to the chips arranged on the wafer represents a permanent insulation layer which is not removed before the chips are diced from the wafer. Instead this permanent insulation layer can advantageously be used with its properties potentially within the framework of the creation of planar contact conductor track structures. Thus after the placing of each chip onto a correspondingly prepared substrate it is possible to use thinner (rewiring) insulation layers, with the process mentioned at the start of creating the contact conductor track structures able to be carried out in a simpler and faster manner.

Only after the dicing of the chips from the wafer will these be applied to a carrier or to a substrate and subjected to the further planar connection technology described at the start. The advantage in this case is that it is possible to work with thin (rewiring) insulation layers since only small thicknesses of the metal layer need to be created as part of the planar conductor structure creation process. The use of thin (rewiring) insulation layers allows the laser ablation process to be carried out in a shorter time in this case, since by comparison with the related art, a smaller layer thickness of (rewiring) insulation material needs to be removed. In addition the disadvantages associated with the laser ablation process in the related art can be almost completely eliminated, since the sensitive chip is already protected on the one hand by the created chip contact surface metallizations and on the other hand by the insulation layer remaining on the chips during dicing.

Expediently a photo-sensitive material, especially one containing a polyimide, benzocyclobutene BCB or an epoxy resist, is used as the insulation layer. The use of a photo-sensitive material as the insulation layer makes it possible to dispense as part of the processing of the chip at a wafer level with the application of corresponding additional photo layers for structuring and embodying the openings in the area of the chip contact surface metallizations provided. This enables the production process to be further simplified and optimized in respect of the costs.

The insulation layer can be applied to the wafer for example by spin-coating, spraying on, dipping, roller-coating or a lamination process.

The layer thickness of the insulation layer can be selected between 10 μm and 500 μm, depending on application. The creation of thick chip contact surface metallizations brings with it the advantage that the chip contact surface metallizations, with a sufficiently large thickness, can be embodied themselves as a heat buffer, which for example can be of advantage in an application in which the chip represents a power semiconductor chip.

The insulation layer can be formed from a single layer or a number of layers. The use of a number of layers can be of advantage for example when thick chip contact surface metallizations are to be embodied. Thus for the application of the photo-sensitive insulating layer at least one further layer, a layer having insulating properties, can be applied to the main side provided with the least one chip contact surface and passivated.

The insulation layer can alternatively be embodied by a lacquer. The lacquer can for example already be applied in structured form to the wafer by using a data-controlled printing method (e.g. by using an inkjet printer). In this case lacquers with high insulation properties are used especially.

In a further embodiment there is provision, before the insulation layer is applied, for the wafer to be applied to an adhesive surface of a carrier and the chips to be diced along predetermined dicing paths, so that on application of the insulation layer the side edges of the chips will be covered with the material of the insulation layer. This also ensures that a chip diced from the wafer has the same thickness of insulation layer on all its surfaces and side edges. This property benefits a downstream method for creating a planar contact conductor track structure since it is possible to work with thin insulation layers.

On dicing of the chips, in a further embodiment an angled flank is created on their side edges in each case in order to facilitate the application of the insulation layer.

There is also provision, for making the openings in the (permanent) insulation layer, for the insulation layer to the exposed using a mask. Alternatively the openings can be made in the insulation layer using a controlled laser exposure system. The openings can be made in the insulation layer using a laser ablation method, a plasma method or using a wet-chemical etching method. This means that the openings can be created in the permanent insulation layer by using known production processes. The latter methods are particularly useful if the insulation layer is formed of a non-photo-sensitive material. The use of plasma or etching methods requires an adapted edge resist structuring in such cases, with the corresponding operations being suitably well known from the related art.

In accordance with a further embodiment of the method, for a chip featuring a plurality of chip contact surface metallizations, the chip contact surface metallizations are created with different thicknesses, with the operations being correspondingly repeated in accordance with the number of different layer thicknesses of chip contact metallizations. If an electronic component with different thicknesses of chip contact surface metallizations is to be created, it is thus proposed to first apply and insulation layer to the wafer which corresponds to the smallest thickness of chip contact surface metallizations. In this case openings can optionally just be provided on those chip contact surfaces on which a chip contact surface metallization of this first thickness is to be created. This is followed by the galvanic creation of the appropriate chip contact surface metallizations. In a next operation a further second insulation layer is applied to the wafer surface. Contact point openings are now created on the chip contact surfaces, on which a chip contact surface metallization is to be created with a thickness corresponding to the thicknesses of the first and second insulation layer. This method can be repeated in the corresponding manner as required for further, even thicker chip contact surface metallizations. In this embodiment it is expedient to subsequently remove all insulation layers except for the first insulation layer, in order to simplify the subsequent further processing in a planar connection process.

An electronic module produced with the method may be used in a chip module which will be electrically connected in planar connection technology with further components and/or with a substrate.

An electronic module includes a chip which is provided on a passivated main side with a least one chip contact surface, on which main side an insulation layer is provided which in the area of the least one chip contact surface has an opening in each case, with in the openings of the insulation layer the chip contact surfaces being provided with a chip contact surface metallization of a predetermined thickness.

Such an electronic module can, as described above, be manufactured at low-cost and especially be used for further processing in planar connection technology. In this case an electronic module preprocessed in this way can be further processed into modules at lower cost by comparison with known chips. An electronic module produced by the method can be especially embodied with heat buffer zones in the form of the chip contact surface metallizations which are difficult to implement or can only be implemented at high cost within the framework of planar connection technology.

In a further embodiment the side edges of the chip are provided with the insulation layer. There can also be provision for the side edges of the chip to have a sloping flank, which makes the further application of the insulation layer provided within the framework of the planar connection process easier. In particular weaknesses in the area of dielectric strength can be especially avoided by this method.

The insulation layer expediently includes a photo-sensitive material, especially one containing a polyamide, benzocyclobutene BCB or an epoxy resist.

The insulation layer can alternately be formed by a lacquer.

The thickness of the chip contact surface metallization of a module is between 10 μm and 500 μm. Basically thicker chip contact surface metallizations can also be created.

The insulation layer can be formed in a further embodiment from a single layer or from a number of layers.

The chip can have a plurality of chip contact surface metallizations which can have a different thickness.

In a concrete embodiment the chip is a power semiconductor chip in which one chip contact surface embodies a control connection and another chip contact surface a load connection, with the chip contact surface metallization of the load connection being greater than that of the control connection. In a further concrete embodiment the chip can be a logic chip or an LED (Light Emitting Diode) chip.

### BRIEF DESCRIPTION OF THE DRAWINGS

These and other aspects and advantages will become more apparent and more readily appreciated from the following description of the exemplary embodiments, taken in conjunction with the accompanying drawings of which:

FIG. 1 is a schematic cross-sectional diagram through a plurality of chips arranged on a wafer after the application of an insulation layer and the embodiment of chip contact surface metallizations,

FIG. 2 is a cross-sectional diagram of an electronic component, and

FIG. 3 is a cross-sectional diagram of an electronic module in which an electronic component is contacted in planar connection technology.

### DETAILED DESCRIPTION OF THE PREFERRED EMBODIMENT

Reference will now be made in detail to the preferred embodiments, examples of which are illustrated in the accompanying drawings, wherein like reference numerals refer to like elements throughout.

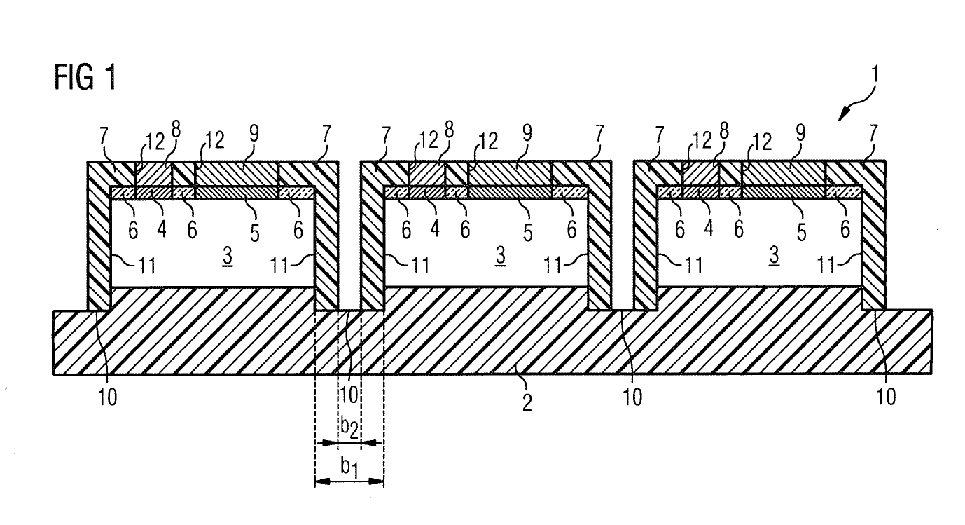

FIG. 1 shows a schematic diagram of a cross-section of typically three chips arranged alongside one another on a wafer 1. The chips 3 are arranged in this case on a carrier 2, e.g. a tape for securing wafers during sawing provided with an adhesive surface. The carrier 2 is connected to the wafer in this case before the separation of the chips 3 from the wafer 1.

Each of the chips 3 typically has two chip contact surfaces 4, 5 on a main side facing away from the carrier 2. The main sides are, as is usual in the processing of wafers, provided with a passivization layer. In a known manner the surfaces of the chip contact surfaces 4, 5 facing away from the chip 3 and the passivization layer 6 lie in roughly one plane.

In preparation for application of an insulation layer 7 to the surface of the chips 3, these are optionally—adhering to the carrier 2—separated from one another. The width of the respective corresponding separation lines between two adjacent chips 3 is labeled b1 in FIG. 1. The separation can for example be undertaken by a sawing process which separates two adjacent chips 3 completely from one another so that this produces a small cutout 10 in the carrier 2.

Subsequently the chips 3 are provided with the insulation layer 7. On the basis of the hollows arising between two adjacent chips 3 not only of the surfaces of the chips 3 embodied in parallel to the carrier 2 but also the side edges 11 or flanks of the chips 3 are covered by the insulation layer 7. The insulation layer 7 can be applied by spin-coating, spraying on, immersion, roller-coating or by a lamination process. Where the insulation layer is embodied by a lacquer, this can be applied by a structured print-technology method.

The thickness of the insulation layer 7 is governed by the thickness of chip contact surface metallizations 8, 9 to be created.

A photo-sensitive material may be used for the insulation layer 7. This can typically be a photo-sensitive polyimide, photo-sensitive benzocyclobutene BCB or a photo-sensitive epoxy-resist. This enables the structuring of the insulation layer to be undertaken using known photo techniques. Thus for example an exposure using mask technologies using data-controlled laser exposure systems can be undertaken so that in both cases highly precise opening structures are able to be created. In this way the corresponding openings in the insulation layer 7 are embodied in the area of the chip contact surfaces 4, 5.

If non-photo-sensitive insulation materials are used for the insulation layer 6, a laser ablation method, a plasma method or also a wet-chemical etching method are especially suitable for structuring. The use of plasma or etching methods requires an adapted etch resist structuring beforehand.

After the embodiment of openings 12 in the area of the chip contact surfaces 4, 5 in the insulation layer 7 the chip contact surface metallizations 8, 9 can be embodied by a galvanization process in the area of the chip contact surfaces 4, 5.

The embodiment of the chip contact surfaces 8, 9 is undertaken in this case at wafer level. The advantage of the proposed method lies in the fact that the application of the insulation layer in the planar state can be undertaken using simple and widely-used coating methods, which makes this method very cost efficient. A wide selection of insulation materials makes it possible to adapt diced electronic components to downstream contacting methods.

The prior sawing, which can especially be at an angle using a so-called V-shape saw blade, especially enables there to be insulation on the critical side edges of the chips at wafer level. This can be achieved by application of lacquer or by use of insulating tapes which are typically applied by a vacuum lamination process.

Multiple coatings enable different layer thicknesses of the chip contact surface metallizations to be obtained, whereby for example heat buffers can be embodied by the chip contact surface metallizations. The structuring can be carried out with high precision even with fine structuring.

In particular with later rewiring on a printed circuit board or to a chip module the use of an automatic optical inspection series for position determination of the components is dispensed with, which enables a structuring, i.e. the creation of the openings in the insulation layer, to be implemented at low cost.

After the creation of the chip contact surface metallizations 8, 9 the chips 3 still present on the wafer 1 will be diced. This is typically done using a sawing process, with the insulation layers applied to the edges 11 of the chips 3 not being adversely affected if possible during this operation. A separation of two adjacent chips 3 is undertaken in the area of the separation line having a width b2.

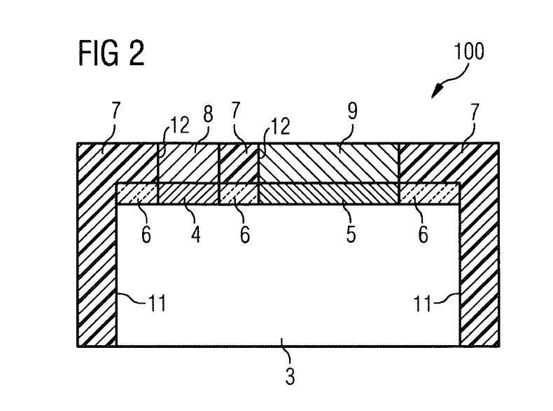

The electronic component 100 resulting from this, which is subsequently also released from the carrier 2, is shown in FIG. 2 The electronic component 100 has two chip contact surface metallizations 8, 9 of equal thickness in this exemplary embodiment. However this is not mandatory. A multiple, sequential execution of the method previously described enables chip contact surface metallizations of different thicknesses to be created. The layer thickness of the chip contact surface metallizations 8, 9 in such cases may be between 10 μm and 500 μm. The creation of thicker chip contact surface metallizations makes sense if such metallizations are to carry out a heat buffer function for example.

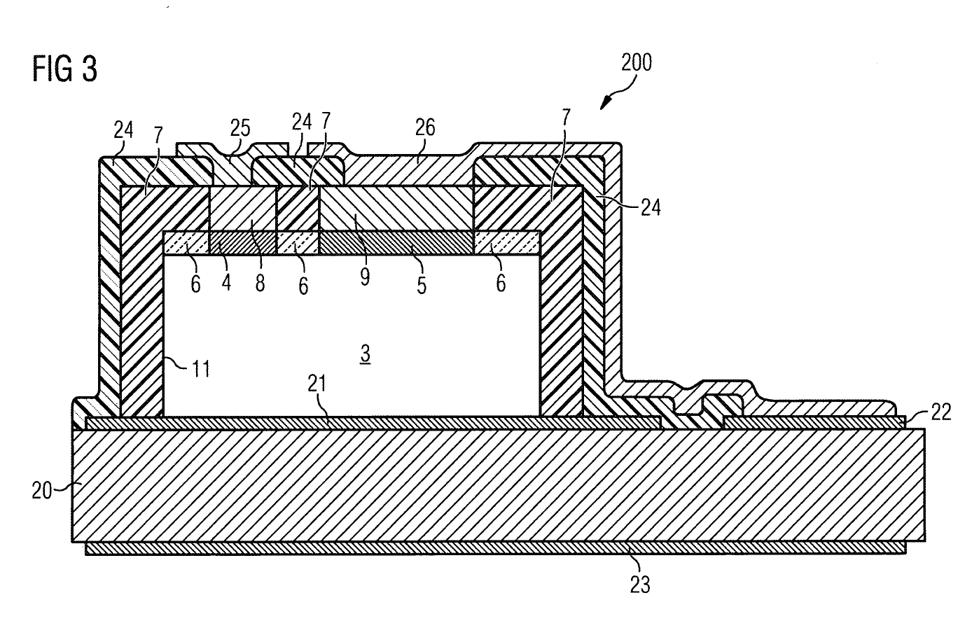

FIG. 3 shows the further processing of an electronic component in accordance with FIG. 2 into a chip module 200.

The planar connection technology described at the start has been applied here. In the exemplary embodiment a substrate 20 has contact surfaces 21, 22, 23 on its front and rear side. The electronic component is arranged on the contact surface 21 and is connected mechanically to the surface by soldering for example. Provided the electronic component has an electrical contact on its rear side an electrical contact is also established here via the connection. An electrical connection of the chip contact surface metallization 9 with the contact surface 22 of the substrate 20 is made via a conductor path structure 26 which runs on a (rewiring) insulation layer 24 of the chip module 200. The chip contact surface 8 is connected to the conductor path structure 25, via which likewise an electrical contact to a contact surface not visible in any great detail in the figure or to a component is made.

The embodied conductor path structure 25, 26 is established by covering the surface of the electronic module applied to the carrier with the insulation layer 24. At the points of the contact surface metallizations 8, 9 openings are made in the (rewiring) insulation layer 24 in order to reveal these. Subsequently a thin metal layer is applied to the entire surface of the insulation layer 24 and the openings made in it. The thin metal layer can be created by sputtering, vapor deposition or another method. This may be, for example, an approximately 50 nm thick titanium layer and an approximately 1 μm thick copper layer. A further light-sensitive tape, generally formed of an insulating material, is then applied to this thin metal layer. This is exposed and developed in accordance with the desired conductive structure. The exposure is undertaken using a mask for example, with the layout of the conductive structure being transferred to the tape. In this case those sections of the photo tape are removed by the mask that are to form the subsequent conductor path structure 25, 26. The non-exposed sections of the photo tape can be removed so that the thin metal layer located beneath them is revealed. By dipping the prepared semi-finished product into an electrolyte bath, especially a copper electrolyte bath, the conductor path structure which has a thickness of 20 μm to 200 μm is grown by galvanic reinforcement.

As a result of the creation of the chip contact surface metallizations 8, 9 already undertaken the conductor path structure 25, 26 can be embodied very thin, since this is needed merely to establish the electrical connections between respective contact surfaces. Possible heat buffer functions or electrical resistances no longer have to be taken into account by this method. In a subsequent operation the photo tape still to be found on the surface is removed in the areas in which no electrically-conducting structure is to be embodied. Finally a differential etching is undertaken in which the thin metallic layer is removed over the entire surface so that only the desired conductor path structure remains.

The advantage of the method using the connection technology described above also described lies in the fact that both the (rewiring) insulation layer 24 and also the permanent insulation layer 7 contribute to electrical insulation. For this reason the insulation layer 24, compared to methods in accordance with the related art, can be embodied significantly thinner, but with the desired dielectric strength still being achieved. The thinner embodiment of the insulation layer allows an easier reshaping, i.e. application of the insulation layer 24 to the three-dimensionally shaped surface of the semi-finished product to be effected. This enables the insulation layer to be applied highly reliably with especially also the critical edges and corners easily achieving the required dielectric strength.

A description has been provided with particular reference to preferred embodiments thereof and examples, but it will be understood that variations and modifications can be effected within the spirit and scope of the claims which may include the phrase “at least one of A, B and C” as an alternative expression that means one or more of A, B and C may be used, contrary to the holding in Superguide v. DIRECTV, 358 F3d 870, 69 USPQ2d 1865 (Fed. Cir. 2004).

1-23. (canceled)

24. A method for producing an electronic component, comprising:
providing a plurality of chips arranged on a wafer with an insulation layer on a main side having a least one chip contact surface and passivated;
providing the insulation layer with openings in an area of the at least one chip contact surface of respective chips;
providing the chip contact surfaces of the respective chips with a chip contact surface metallization of a predetermined thickness; and
separating the chips from the wafer.

25. The method as claimed in claim 24, wherein the insulation layer includes a photo-sensitive material, containing at least one of a polyamide, benzocyclobutene and an epoxy resist.

26. The method as claimed in claim 25, wherein said providing of the insulation layer includes at least one of applying by spin-coating, spraying on, immersion, roller-coating and a lamination process.

27. The method as claimed in claim 26, wherein a selected layer thickness of the insulation layer is between 10 μm and 500 μm.

28. The method as claimed in claim 27, wherein the insulation layer is formed of multiple layers.

29. The method as claimed in claim 27, wherein the insulation layer is formed by a lacquer.

30. The method as claimed in claim 29,
wherein said separating of the chips occurs along predetermined separation paths prior to said providing of the insulation layer,
wherein said method further comprises, prior to said providing of the insulation layer, applying the wafer to an adhesive surface of a carrier, and
wherein during said providing of the insulation layer, side edges of the chips are covered by the insulation layer.

31. The method as claimed in claim 30, wherein said separating of the chips includes creating a edge running at an angle on the side edges of each chip, to facilitate said providing of the insulation layer.

32. The method as claimed claim 31, wherein said providing of the insulation layer includes exposing the insulation layer using a mask to make the openings in the insulation layer.

33. The method as claimed in claim 31, wherein said providing of the insulation layer includes using a controlled laser exposure system to make the openings in the insulation layer.

34. The method as claimed in claim 31, wherein said providing of the insulation layer includes making the openings in the insulation layer using at least one of a laser ablation method, a plasma method and a wet-chemical etching method.

35. The method as claimed in claim 34, wherein each of the chips has a plurality of chip contact surface metallizations, and
wherein said providing the chip contact surface metallization is repeated with variation to produce different thicknesses of the chip contact metallizations.

36. A chip module electrically connected in planar connection technology with at least one of a substrate and other components, said chip module comprising:
an electronic component including a chip having a passivated main side with at least one chip contact surface, each chip contact surface provided with an insulation layer having an opening and a chip contact surface metallization of a predetermined thickness in the opening of the insulation layer.

37. An electronic component, comprising:
a chip having a passivated main side with at least one chip contact surface, each chip contact surface provided with an insulation layer having an opening and a chip contact surface metallization of a predetermined thickness in the opening of the insulation layer.

38. The electronic component as claimed in claim 37, wherein the chip has side edges on which the insulation layer is formed.

39. The electronic component as claimed in claim 38, wherein the side edges of the chip have an edge running at an angle.

40. The electronic component as claimed in claim 39, wherein the insulation layer includes a photo-sensitive material containing at least one of a polyamide, benzocyclobutene and an epoxy resist.

41. The electronic component as claimed in claim 40, wherein the insulation layer is formed by a lacquer.

42. The electronic component as claimed in claim 41, wherein the thickness of the chip contact surface metallization is between 10 μm and 500 μm.

43. The electronic component as claimed in claim 42, wherein the insulation layer is formed from multiple layers.

44. The electronic component as claimed in claim 43, wherein the chip has a plurality of chip contact surface metallizations of different thicknesses.

45. The electronic component as claimed in claim 44,
wherein the chip is a power semiconductor chip,
wherein a first chip contact surface has a control connection and a second chip contact surface has a load connection, and
wherein the chip contact surface metallization of the load connection is thicker than the chip contact surface metallization of the control connection.

46. The electronic component as claimed in claim 44, wherein the chip is one of a logic chip and a light emitting diode chip.
